(19) United States
(12) Patent Application Publication
(10) Pub. No.: US 2026/0299415 A1
(43) Pub. Date: Oct. 1, 2026

(54) PHOTOSENSITIVE RESIN COMPOSITION, PHOTOSENSITIVE ELEMENT, METHOD FOR FORMING RESIST PATTERN, AND METHOD FOR PRODUCING PRINTED WIRING BOARD

(71) Applicant: Resonac Corporation, Tokyo (JP)

(72) Inventors: Natsuki TODA, Tokyo (JP); Taku SAWAKI, Tokyo (JP); Kensuke YOSHIHARA, Tokyo (JP); Yosuke KAGUCHI, Tokyo (JP)

(73) Assignee: Resonac Corporation, Tokyo (JP)

(21) Appl. No.: 19/477,944

(22) PCT Filed: Dec. 9, 2024
(86) PCT No.: PCT/JP2024/043453

§ 371 Date: Oct. 23, 2025

(30) Foreign Application Priority Data
Dec. 11, 2023 (WO) PCT/JP2023/044246

(51) Int. Cl. G03F 7/033; G03F 7/028; H05K 3/10

(52) U.S. Cl. CPC G03F 7/033; G03F 7/028; H05K 3/10

(57) ABSTRACT

A photosensitive resin composition according to an aspect of the present disclosure contains: a binder polymer; a photopolymerizable compound; and a photopolymerization initiator, and the binder polymer has a structural unit derived from acrylic acid and a structural unit derived from methacrylic acid.

### TECHNICAL FIELD

The present disclosure relates to a photosensitive resin composition, a photosensitive element, a method of forming a resist pattern, and a method of manufacturing a printed wiring board.

### BACKGROUND ART

In the field of manufacturing printed wiring boards, photosensitive resin compositions and photosensitive elements including photosensitive resin compositions and layers (hereinafter, also referred to as “photosensitive layers”) formed using supports and the photosensitive resin compositions on the supports have widely been used as resist materials to be used in the etching process or plating process (for example, see PTL 1 and PTL 2 listed below).

A printed wiring board is manufactured, for example, by the following procedure using a photosensitive element as described above. First, a photosensitive layer of the photosensitive element is laminated on a circuit formation substrate such as a copper-clad laminate. Next, predetermined parts of the photosensitive layer are exposed to light via a photomask to form photocured portions. At this time, the support is peeled off before or after the exposure. Thereafter, a region of the photosensitive layer other than the photocured portions is removed with a developer, and a resist pattern is formed on the substrate. Next, etching process or plating process is applied using the resist pattern as a resist to form a conductor pattern on the substrate, and the resist is finally released and removed.

### CITATION LIST

### Patent Literature

[PTL 1] Japanese Patent Application Publication No, 2009-003177
[PTL 2] Japanese Patent Application Publication No. 2013-061556

### SUMMARY OF INVENTION

### Technical Problem

In recent years, the numbers of layers in substrates have increased with enhancement of performance of semiconductor packages and the like. In a case of a multilayer substrate (stacked substrate), unevenness occurs in the substrate due to wiring in a lower layer, and followability to the unevenness of the substrate has been required when a photosensitive layer is laminated using a photosensitive element in the substrate. However, releasability when the photosensitive layer after being cured is released from the substrate may be degraded due to an improvement in followability to the unevenness of the substrate, and it is difficult to achieve both the followability and the releasability.

An object of the present disclosure is to provide a photosensitive resin composition and a photosensitive element that are excellent both in followability and releasability, and a method of forming a resist pattern and a method of manufacturing a printed wiring board using the same.

### Solution to Problem

In order to achieve the above object, an aspect of the present disclosure relates to a photosensitive resin composition, a photosensitive element, a method of forming a resist pattern, and a method of manufacturing a printed wiring board below.
[1] A photosensitive resin composition including: a binder polymer; a photopolymerizable compound; and a photopolymerization initiator, in which the binder polymer has a structural unit derived from acrylic acid and a structural unit derived from methacrylic acid.
[2] The photosensitive resin composition according to [1] above, in which the binder polymer further has a structural unit derived from a (meth)acrylate compound having an alicyclic structure.
[3] The photosensitive resin composition according to [1] or [2] above, in which the binder polymer further has a structural unit derived from a (meth)acrylic acid aryl ester.
[4] The photosensitive resin composition according to any one of [1] to [3] above, in which a total content of the structural unit derived from acrylic acid and the structural unit derived from methacrylic acid is 25% by mass to 45% by mass with respect to a total mass of structural units derived from polymerizable monomers constituting the binder polymer.
[5] The photosensitive resin composition according to any one of [1] to [4] above, in which a content of a structural unit derived from styrene or a styrene derivative in the binder polymer is 0% by mass to 19% by mass with respect to a total mass of structural units derived from polymerizable monomers constituting the binder polymer.
[6] A photosensitive element including: a support; and a photosensitive layer formed on the support using the photosensitive resin composition according to any one of [1] to [5] above.
[7] A method of forming a resist pattern, including: forming a photosensitive layer on a substrate using the photosensitive resin composition according to any one of [1] to [5] above; irradiating at least a part of the photosensitive layer with active rays to form a photocured portion; and removing an unphotocured portion of the photosensitive layer from the substrate to form a resist pattern.
[8] A method of forming a resist pattern, including: forming a photosensitive layer on a substrate using the photosensitive element according to [6] above; irradiating at least a part of the photosensitive layer with active rays to form a photocured portion; and removing an unphotocured portion of the photosensitive layer from the substrate to form a resist pattern.
[9] A method of manufacturing a printed wiring board, including: performing etching process or plating process on a substrate with a resist pattern formed thereon by the method of forming a resist pattern according to [7] or [8] above to form a conductor pattern.

### Advantageous Effects of Invention

According to the present disclosure, it is possible to provide a photosensitive resin composition and a photosensitive element that are excellent in both followability and releasability, and a method of forming a resist pattern and a method of manufacturing a printed wiring board using the same.

### BRIEF DESCRIPTION OF DRAWINGS

FIG. 1 is a schematic sectional view illustrating an embodiment of a photosensitive element.

### DESCRIPTION OF EMBODIMENTS

Hereinafter, an embodiment for carrying out the present disclosure will be described in detail. However, the present invention is not limited to the following embodiment.

In the present specification, the term “process” includes not only an independent process but also a process that cannot be clearly distinguished from other processes as long as a prescribed effect of the process is achieved. The term “layer” includes not only a structure with a shape formed on an entire surface but also a structure with a shape formed on a part of the surface in observation in a plan view. Numerical ranges indicated using “to” indicate ranges including the numerical values stated before and after “to” as the minimum and maximum values, respectively. In numerical ranges stated in stages in the present specification, an upper limit value or a lower limit value of a numerical range in a certain stage may be replaced with an upper limit value or a lower limit value of a numerical range in another stage. In a numerical range described in the present specification, an upper limit value or a lower limit value of the numerical range may be replaced with values indicated in the Examples.

As used in the present specification, “(meth)acrylate” means at least either “acrylate” or “methacrylate” corresponding thereto. The same applies to other similar expressions such as “(meth)acryloyl”.

In the present specification, in a case where a plurality of substances corresponding to each component are present in a composition, the amount of each component in a photosensitive resin composition means the total amount of the plurality of substances that are present in the composition unless otherwise particularly specified. In the present specification, the term “solid content” refers to a nonvolatile content from which substances that volatilize (water, a solvent, and the like) are excluded in the photosensitive resin composition. In other words, “solid content” refers to components, which remain without volatilization after drying of the photosensitive resin composition described later, other than the solvent and also includes components in a liquid form, a starch syrupy-like form, or a wax form at a room temperature (25° C.).

### [Photosensitive Resin Composition]

The photosensitive resin composition according to the present embodiment contains (A) a binder polymer (hereinafter, referred to as a “component (A)” in some cases), (B) a photopolymerizable compound (hereinafter, referred to as a “component (B)” in some cases), and (C) a photopolymerization initiator (hereinafter, referred to as a “component (C)” in some cases). The component (A) includes a structural unit derived from acrylic acid and a structural unit derived from methacrylic acid. Hereinafter, each component that can be contained in the photosensitive resin composition will be described in detail.

### Component (A): Binder Polymer

The photosensitive resin composition includes one or more kinds of component (A). The component (A) has a structural unit derived from acrylic acid (hereinafter, referred to as a “first structural unit” in some cases) and a structural unit derived from methacrylic acid (hereinafter, referred to as a “second structural unit in some cases). The component (A) may be a binder polymer (a) having a first structural unit and a second structural unit in one molecule. The component (A) can be manufactured through radical polymerization of a polymerizable monomer including acrylic acid and methacrylic acid.

The photosensitive resin composition according to the present embodiment can improve followability and releasability after curing of the photosensitive layer formed from the photosensitive resin composition by containing the binder polymer including the first structural unit and the second structural unit as the component (A).

The content of the first structural unit in the component (A) may be equal to or greater than 15% by mass, equal to or greater than 18% by mass, equal to or greater than 19% by mass, or equal to or greater than 20% by mass from the viewpoint of followability and releasability and may be equal to or less than 27% by mass, equal to or less than 26% by mass, equal to or less than 25% by mass, or equal to or less than 24% by mass from the viewpoint of alkali resistance with respect to the total mass of the structural units derived from the polymerizable monomers constituting the binder polymer. The content of the first structural unit in the component (A) may be 15% by mass to 27% by mass, 18% by mass to 26% by mass, 19% by mass to 25% by mass, or 20% by mass to 24% by mass with respect to the total mass of the structural units derived from the polymerizable monomers constituting the binder polymer.

The content of the second structural unit in the component (A) may be equal to or greater than 3% by mass, equal to or greater than 5% by mass, equal to or greater than 10% by mass, equal to or greater than 15% by mass, or equal to or greater than 20% by mass from the viewpoint of resolution and adhesion and may be equal to or less than 35% by mass, equal to or less than 30% by mass, equal to or less than 28% by mass, equal to or less than 26% by mass, or equal to or less than 25% by mass from the viewpoint of alkali resistance, followability, and releasability with respect to the total mass of the structural units derived from the polymerizable monomers constituting the binder polymer. The content of the second structural unit in the component (A) may be 3% by mass to 35% by mass, 5% by mass to 30% by mass, 10% by mass to 28% by mass, 15% by mass to 26% by mass, or 20% by mass to 25% by mass with respect to the total mass of the structural units derived from the polymerizable monomers constituting the binder polymer.

The total content of the first structural unit and the second structural unit in the component (A) may be equal to or greater than 25% by mass, equal to or greater than 30% by mass, equal to or greater than 35% by mass, or equal to or greater than 40% by mass and may be equal to or less than 65% by mass, equal to or less than 60% by mass, equal to or less than 55% by mass, equal to or less than 50% by mass, or equal to or less than 45% by mass with respect to the total mass of the structural units derived from the polymerizable monomers constituting the binder polymer from the viewpoint of followability, releasability, and photosensitive properties (for example, resolution and adhesion). The total content of the first structural unit and the second structural unit in the component (A) may be 25% by mass to 45% by mass with respect to the total mass of the structural units derived from the polymerizable monomers constituting the binder polymer from the viewpoint of followability, releasability, and photosensitive properties.

The component (A) may further have a structural unit (hereinafter, referred to as a “third structural unit” in some cases) derived from a (meth)acrylate compound having an alicyclic structure from the viewpoint of resolution and adhesion of the photosensitive resin composition. Examples of (meth)acrylate having an alicyclic structure include cyclohexyl (meth)acrylate, isobornyl (meth)acrylate, adamantyl (meth)acrylate, cyclopentanyl (meth)acrylate and dicyclopentanyl (meth)acrylate,

The content of the third structural unit in the component (A) may be equal to or greater than 7% by mass, equal to or greater than 10% by mass, equal to or greater than 15% by mass, equal to or greater than 20% by mass, equal to or greater than 25% by mass, or equal to or greater than 30% by mass from the viewpoint of resolution and adhesion of the photosensitive resin composition and may be equal to or less than 70% by mass, equal to or less than 65% by mass, equal to or less than 60% by mass, equal to or less than 50% by mass, or equal to or less than 40% by mass from the viewpoint of developability of the photosensitive resin composition with respect to the total mass of the structural units derived from the polymerizable monomers constituting the binder polymer. The content of the third structural unit in the component (A) may be equal to or greater than 18% by mass, equal to or greater than 20% by mass, or equal to or greater than 25% by mass and may be equal to or less than 34% by mass, equal to or less than 33% by mass, or equal to or less than 32% by mass from the viewpoint of achieving both followability and releasability of the photosensitive resin composition with a satisfactory balance with respect to the total mass of the structural units derived from the polymerizable monomers constituting the binder polymer.

The component (A) may further have a structural unit derived from (meth)acrylic acid aryl ester (hereinafter, referred to as a “fourth structural unit” in some cases) from the viewpoint of further excellent followability. Examples of (meth)acrylic acid aryl ester include benzyl (meth)acrylate, phenyl (meth)acrylate, and naphthyl (meth)acrylate. In a case where the component (A) has the fourth structural unit, the content of the fourth structural unit may be equal to or greater than 5% by mass, equal to or greater than 10% by mass, equal to or greater than 15% by mass, equal to or greater than 20% by mass, equal to or greater than 21% by mass, or equal to or greater than 22% by mass and may be equal to or less than 40% by mass, equal to or less than 35% by mass, equal to or less than 30% by mass, equal to or less than 28% by mass, equal to or less than 26% by mass, or equal to or less than 25% by mass from the viewpoint of more excellent followability with respect to the total mass of the structural units derived from the polymerizable monomers constituting the binder polymer. The content of the fourth structural unit may be equal to or greater than 21% by mass, equal to or greater than 22% by mass, or equal to or greater than 23% by mass and may be equal to or less than 35% by mass, equal to or less than 30% by mass, equal to or less than 28% by mass, equal to or less than 26% by mass, or equal to or less than 25% by mass from the viewpoint of achieving both followability and releasability of the photosensitive resin composition with a more satisfactory balance with respect to the total mass of the structural units derived from the polymerizable monomers constituting the binder polymer,

The component (A) may further have a structural unit (hereinafter, referred to as a “fifth structural unit” in some cases) derived from styrene or a styrene derivative from the viewpoint of resolution and adhesion of the photosensitive resin composition. Examples of the styrene derivative include vinyltoluene, o-methylstyrene, p-methylstyrene and p-ethylstyrene. The component (A) may not have the fifth structural unit from the viewpoint of followability and releasability.

The content of the fifth structural unit in the component (A) may be 0% by mass to 19% by mass, 0% by mass to 17% by mass, 0% by mass to 15% by mass, 0% by mass to 10% by mass, or 0% by mass to 5% by mass from the viewpoint of followability and releasability with respect to the total mass of the structural units derived from the polymerizable monomers constituting the binder polymer.

The component (A) may further have structural units derived from polymerizable monomers other than the above-mentioned polymerizable monomers (hereinafter, also referred to as “other monomers”). Examples of other monomers include (meth)acrylic acid alkyl esters (except for the (meth)acrylate compound having an alicyclic structure described above) such as (meth)acrylic acid methyl ester, (meth)acrylic acid ethyl ester, (meth)acrylic acid butyl ester, 2-ethylhexyl (meth)acrylate, β-styryl (meth)acrylic acid, hydroxyethyl (meth)acrylate, furfuryl (meth)acrylate, tetrahydrofurfuryl (meth)acrylate, dimethylaminoethyl (meth)acrylate, diethylaminoethyl (meth)acrylate, glycidyl (meth)acrylate, 2,2,2-trifluoroethyl (meth)acrylate, 2,2,3,3-tetrafluoropropyl (meth)acrylate, β-furyl (meth)acrylic acid, maleic acid, maleic anhydride, maleic acid monoalkyl ester, fumaric acid, cinnamic acid, α-cyanocinnamic acid, itaconic acid, crotonic acid, and propiolic acid. One kind of these may be used alone, or two or more kinds of these may be used in combination. In a case where the component (A) has structural units derived from other monomers (for example, a structural unit derived from (meth)acrylic acid alkyl ester), the content thereof may be equal to or less than 30% by mass, equal to or less than 25% by mass, equal to or less than 20% by mass, equal to or less than 15% by mass, or equal to or less than 5% by mass with respect to the total mass of the structural units derived from the polymerizable monomers constituting the binder polymer.

The weight average molecular weight (Mw) of the component (A) may be 10000 to 80000, 15000 to 70000, 20000 to 60000, 23000 to 50000, or 25000 to 50000. Resolution and developability tend to be improved when Mw is equal to or less than 80000, and there is a trend that flexibility of a cured film is improved and chipping and peeling-off of the resist pattern are unlikely to occur when Mw is equal to or greater than 10000. A dispersity (Mw/Mn) of the component (A) may be 1.0 to 3.0, 1.0 to 2.5, or 1.0 to 2.3. There is a trend that resolution is further improved as the dispersity decreases.

Mw can be measured by gel permeation chromatography (GPC) using a standard polystyrene calibration curve, for example. More specifically, it is possible to measure Mw under conditions described in Examples.

The acid value of the component (A) may be 100 mgKOH/g to 200 mgKOH/g, or may be 140 mgKOH/g to 200 mgKOH/g, 140 mgKOH/g to 190 mgKOH/g, or 140 mgKOH/g to 180 mgKOH/g from the viewpoint of developability and releasability. It is possible to sufficiently suppress an increase in development time by the acid value of the component (A) being equal to or greater than 140 mgKOH/g, and it becomes easy to improve developer resistance (adhesion) of a cured article of the photosensitive resin composition by the acid value of the component (A) being equal to or less than 200 mgKOH/g. The acid value of the component (A) can be adjusted by a structural unit derived from acrylic acid and a structural unit derived from methacrylic acid. The acid value of the component (A) can be measured in accordance with JIS K6901: 2008 5.3.2.

The glass transition temperature (Tg) of the component (A) may be 80° C. to 140° C., 80° C. to 130° C., 80° C. to 120° C., 90° C. to 115° C., or 95° C. to 110° C. It becomes easy to improve a laminating property of the photosensitive layer formed from the photosensitive resin composition when Tg of the component (A) is equal to or greater than 80° C., and it becomes easy to improve adhesion, resolution, and storage stability of the photosensitive resin composition when Tg is equal to or less than 130° C. Tg of the component (A) is a value obtained in accordance with a Fox equation and can be calculated from the mass of each polymerizable monomer constituting the component (A) and Tg of a homopolymer of each polymerizable monomer.

The content of the component (A) may be equal to or greater than 20 parts by mass, equal to or greater than 30 parts by mass, equal to or greater than 40 parts by mass, or equal to or greater than 50 parts by mass from the viewpoint of film moldability and may be equal to or less than 80 parts by mass, equal to or less than 70 parts by mass, or equal to or less than 60 parts by mass from the viewpoint of sensitivity and resolution with respect to 100 parts by mass of the total amount of the component (A) and the component (B).

### Component (B): Photopolymerizable Compound

The photosensitive resin composition includes one or more kinds of component (B). The component (B) may be any compound that is polymerized by light and may be, for example, a compound having an ethylenic unsaturated bond. The component (B) may include a multifunctional monomer having two or more reactive groups that react by radicals. The component (B) may include a bisphenol A type (meth)acrylate compound from the viewpoint of developability, resolution, and releasability after curing.

Examples of the bisphenol A type (meth)acrylate compound include 2,2-bis(4-((meth)acryloxypolyethoxy)phenyl)propane, 2,2-bis(4-((meth)acryloxypolypropoxy)phenyl)propane, 2,2-bis(4-((meth)acryloxypolybutoxy)phenyl)propane, and 2,2-bis(4-((meth)acryloxypolyethoxy polypropoxy)phenyl)propane. The component (B) may include 2,2-bis(4-((meth)acryloxypolyethoxy)phenyl)propane from the viewpoint of resolution and releasability. As 2,2-bis(4-((meth)acryloxypolyethoxy)phenyl)propane, a compound having 10 or more oxyethylene groups may be used, a compound having less than 10 oxyethylene groups may also be used, and a compound having 10 or more oxyethylene groups and a compound having less than 10 oxyethylene groups may be used together. Examples of 2,2-bis(4-((meth)acryloxypolyethoxy)phenyl)propane include 2,2-bis(4-((meth)acryloxypentaethoxy)phenyl)propane and 2,2-bis(4-((meth)acryloxydiethoxy)phenyl)propane.

The content of the bisphenol A type (meth)acrylate compound may be equal to or greater than 20% by mass, equal to or greater than 40% by mass, equal to or greater than 60% by mass, or equal to or greater than 80% by mass and may be equal to or less than 100% by mass or equal to or less than 95% by mass with respect to the total amount of the component (B) from the viewpoint of resolution. In a case where 2,2-bis(4-((meth)acryloxypolyethoxy)phenyl)propane is used as the bisphenol A type (meth)acrylate compound, the content of the compound having 10 or more oxyethylene groups may be equal to or greater than 20% by mass, equal to or greater than 40% by mass, equal to or greater than 60% by mass, or equal to or greater than 70% by mass and may be equal to or less than 100% by mass, equal to or less than 95% by mass, or equal to or less than 90% by mass with respect to the total amount of the component (B).

The component (B) may include an, α,β-unsaturated ester compound obtained by causing α,β-unsaturated carboxylic acid to react with a polyhydric alcohol from the viewpoint of resolution and flexibility. Examples of the α,β-unsaturated ester compound include polyalkylene glycol di(meth)acrylates such as polyethylene glycol di(meth)acrylate, polypropylene glycol di(meth)acrylate, EO-modified polypropylene glycol, trimethylolpropane di(meth)acrylate, trimethylolpropane tri(meth)acrylate, EO-modified trimethylolpropane tri(meth)acrylate, PO-modified trimethylolpropane tri(meth)acrylate, EO/PO-modified trimethylolpropane tri(meth)acrylate, tetramethylolmethane tri(meth)acrylate, and tetramethylolmethane tetra(meth)acrylate.

The component (B) may include a compound having three or more (meth)acryloyl groups from the viewpoint of sensitivity and adhesion. Examples of the compound having three or more (meth)acryloyl groups include trimethylolpropane tri(meth)acrylate, EO-modified trimethylolpropane tri(meth)acrylate, PO-modified trimethylolpropane tri(meth)acrylate, EO/PO-modified trimethylolpropane tri(meth)acrylate, EO-modified pentaerythritol tetra(meth)acrylate, EO-modified ditrimethylolpropane tetra(meth)acrylate, and EO-modified dipentaerythritol hexa (meth)acrylate.

The content of the α,β-unsaturated ester compound may be equal to or greater than 20% by mass or equal to or greater than 30% by mass from the viewpoint of flexibility and may be equal to or less than 70% by mass or equal to or less than 60% by mass from the viewpoint of resolution with respect to the total amount of the component (B).

The photosensitive resin composition may include photopolymerizable compounds other than the bisphenol A type (meth)acrylate compound and the α,β-unsaturated ester compound as the component (B).

Examples of other photopolymerizable compounds include nonylphenoxypolyethylene oxyacrylate, a phthalic acid compound, (meth)acrylic acid alkyl ester, and a photopolymerizable compound (such as an oxetane compound) having at least one cation polymerizable cyclic ether group in a molecule, Other photopolymerizable compounds may be at least one kind selected from the group consisting of nonylphenoxypolyethylene oxyacrylate and a phthalic acid compound from the viewpoint of resolution, adhesion, the resist shape, and releasability after curing.

Examples of nonylphenoxypolyethylene oxyacrylate include nonylphenoxytriethylene oxyacrylate, nonylphenoxytetraethylene oxyacrylate, nonylphenoxypentaethylene oxyacrylate, nonylphenoxyhexaethylene oxyacrylate, nonylphenoxyheptaethylene oxyacrylate, nonylphenoxyoctaethylene oxyacrylate, nonylphenoxynonaethylene oxyacrylate, nonylphenoxydecaethylene oxyacrylate, and nonylphenoxyundecaethylene oxyacrylate.

Examples of the phthalic acid-based compound include γ-chloro-β-hydroxypropyl-β′-(meth)acryloyloxyethyl-o-phthalate (also known as 3-chloro-2-hydroxypropyl-2-(meth)acryloyloxyethyl phthalate), β-hydroxyethyl-β′-(meth)acryloyloxyethyl-o-phthalate, and β-hydroxypropyl-β′-(meth)acryloyloxyethyl-o-phthalate.

In a case where the component (B) includes other photopolymerizable compounds, the content of other photopolymerizable compounds may be equal to or greater than 1% by mass, equal to or greater than 3% by mass, or equal to or greater than 5% by mass and may be equal to or less than 30% by mass, equal to or less than 25% by mass, or equal to or less than 20% by mass with respect to the total amount of the component (B) from the viewpoint of resolution, adhesion, the resist shape, and releasability after curing.

The component (B) may include, among the above-described compounds, a compound having a total of 2 to 40 oxygen ethylene groups (EO groups) and/or oxypropylene groups (PO groups) in a molecule from the viewpoint of adhesion and resolution. The total number of EO groups and/or PO groups may be 2 to 40 or 2 to 30 from the viewpoint of adhesion and resolution.

The content of the compound having a total of 2 to 40 EO groups and/or PO groups may be 28 by mass to 15% by mass, 4% by mass to 12% by mass, or 5% by mass to 8% by mass from the viewpoint of adhesion and resolution with respect to the total amount of the component (B).

The content of the component (B) may be equal to or greater than 3% by mass, equal to or greater than 108 by mass, equal to or greater than 25% by mass, equal to or greater than 30% by mass, or equal to or greater than 40% by mass from the viewpoint of sensitivity and resolution and may be equal to or less than 70% by mass, equal to or less than 60% by mass, equal to or less than 50% by mass, or equal to or less than 45% by mass from the viewpoint of film moldability, releasability, and the like with respect to the total amount of solid content in the photosensitive resin composition. Although an increase in content of the component (B) included in the photosensitive resin composition in order to improve followability has been studied in the related art, photosensitive properties and releasability may be degraded by increasing the content of the component (B). The photosensitive resin composition according to the present embodiment can form a photosensitive layer that is excellent in followability without increasing the content of the component (B), by using the binder polymer having the above-described specific structure.

### Component (C): Photopolymerization Initiator

The photosensitive resin composition includes one or more kinds of components (C). The component (C) is not particularly limited as long as the component can polymerize the component (B), and the component (C) can be appropriately selected from typically used photopolymerization initiators.

Examples of the component (C) include: hexaarylbiimidazole compounds; aromatic ketone compounds such as benzophenone, 2-benzyl-2-dimethylamino-1-(4-morpholinophenyl)-1-butanone, 2-(dimethylamino)-2-[(4-methylphenyl)methyl]-1-[4-(4-morpholinyl)phenyl]-1-butanone, 4-(2-hydroxyethoxy)phenyl-2-(hydroxy-2-propyl) ketone, and 2-methyl-1-[4-(methylthio)phenyl]-2-morpholino-propanone-1; quinone compounds such as alkylanthraquinone; benzoin ether compounds such as benzoin alkyl ether; benzoin compounds such as benzoin and alkylbenzoin; benzyl derivatives such as benzyldimethyl ketal; and phosphine oxide compounds such as bis(2,4,6-trimethylbenzoyl)-phenylphosphine oxide, bis(2,6-dimethylbenzoyl)-2,4,4-trimethyl-pentylphosphine oxide, and (2,4,6-trimethylbenzoyl) ethoxyphenylphosphine oxide.

The component (C) may include a hexaarylbiimidazole compound from the viewpoint of capability of suppressing permeation of the photosensitizer to the polyethylene film. An aryl group in the hexaarylbiimidazole compound may be a phenyl group or the like. The hydrogen atom bonded to the aryl group in the hexaarylbiimidazole compound may be substituted with a halogen atom (such as a chlorine atom).

The hexaarylbiimidazole compound may be a 2,4,5-triarylimidazole dimer. Examples of the 2,4,5-triarylimidazole dimer include a 2-(o-chlorophenyl)-4,5-diphenylimidazole dimer, a 2-(o-chlorophenyl)-4,5-bis-(m-methoxyphenyl) imidazole dimer, and a 2-(p-methoxyphenyl)-4,5-diphenylimidazole dimer. The hexaarylbiimidazole compound is preferably 2-(o-chloriphenyl)-4,5-diphenylimidazole dimer and is more preferably 2,2-bis(o-chlorophenyl)-4,5-4′,5′-tetraphenyl-1,2′-biimidazole from the viewpoint of capability of further suppressing permeation of the photosensitizer to the polyethylene film.

The content of the hexaarylbiimidazole compound may be equal to or greater than 90% by mass, equal to or greater than 95% by mass, or equal to or greater than 99% by mass with respect to the total amount of the component (C). The component (C) may consist only of the hexaarylbiimidazole compound.

The content of the component (C) may be equal to or greater than 0.1% by mass, equal to or greater than 0.5% by mass, or equal to or greater than 1.0% by mass and may be equal to or less than 20% by mass, equal to or less than 10% by mass, or equal to or less than 5% by mass with respect to the total amount of the solid content in the photosensitive resin composition from the viewpoint of sensitivity and adhesion.

### Component (D): Sensitizer

From the viewpoint of effectively utilizing the absorption wavelengths of active rays used for exposure, the photosensitive resin composition may further contain a component (D): a sensitizer.

Examples of the component (D) include a dialkylaminobenzophenone compound, a pyrazoline compound, an anthracene compound, a coumarin compound, a xanthone compound, a thioxanthone compound, an oxazole compound, a benzoxazole compound, a thiazole compound, a benzothiazole compound, a triazole compound, a stilbene compound, a triazine compounds, a thiophene compound, a naphthalimide compound, a triarylamine compound, and an aminoacridine compound. The component (D) may include at least one kind selected from the group consisting of a pyrazoline compound and an anthracene compound from the viewpoint of resolution.

Examples of pyrazoline compounds include 1-(4-methoxyphenyl)-3-styryl-5-phenyl-pyrazoline, 1-phenyl-3-(4-methoxystyryl)-5-(4-methoxyphenyl)-pyrazoline, 1,5-bis-(4-methoxyphenyl)-3-(4-methoxystyryl)-pyrazoline, 1-(4-isopropylphenyl)-3-styryl-5-phenyl-pyrazoline, 1-phenyl-3-(4-isopropylstyryl)-5-(4-isopropylphenyl)-pyrazoline, 1,5-bis-(4-isopropylphenyl)-3-(4-isopropylstyryl)-pyrazoline, 1-(4-methoxyphenyl)-3-(4-tert-butyl-styryl)-5-(4-tert-butyl-phenyl)-pyrazoline, 1-(4-tert-butyl-phenyl)-3-(4-methoxystyryl)-5-(4-methoxyphenyl)-pyrazoline, 1-(4-isopropyl-phenyl)-3-(4-tert-butyl-styryl))-5-(4-tert-butyl-phenyl)-pyrazoline, 1-(4-tert-butyl-phenyl)-3-(4-isopropyl-styryl)-5-(4-isopropyl-phenyl)-pyrazoline, 1-(4-methoxyphenyl)-3-(4-isopropylstyryl)-5-(4-isopropylphenyl)-pyrazoline, 1-(4-isopropyl-phenyl)-3-(4-methoxystyryl)-5-(4-methoxyphenyl)-pyrazoline, 1-phenyl-3-(3,5-dimethoxystyryl)-5-(3,5-dimethoxyphenyl)-pyrazoline, 1-phenyl-3-(3,4-dimethoxystyryl)-5-(3,4-dimethoxyphenyl)-pyrazoline, 1-phenyl-3-(2,6-dimethoxystyryl)-5-(2,6-dimethoxyphenyl)-pyrazoline, 1-phenyl-3-(2,5-dimethoxystyryl)-5-(2,5-dimethoxyphenyl)-pyrazoline, 1-phenyl-3-(2,3-dimethoxystyryl)-5-(2,3-dimethoxyphenyl)-pyrazoline, 1-phenyl-3-(2,4-dimethoxystyryl)-5-(2,4-dimethoxyphenyl)-pyrazoline, 1-(4-methoxyphenyl)-3-(3,5-dimethoxystyryl)-5-(3,5-dimethoxyphenyl)-pyrazoline, 1-(4-methoxyphenyl)-3-(3,4-dimethoxystyryl)-5-(3,4-dimethoxyphenyl)-pyrazoline, 1-(4-methoxyphenyl)-3-(2,6-dimethoxystyryl)-5-(2,6-dimethoxyphenyl)-pyrazoline, 1-(4-methoxyphenyl)-3-(2,5-dimethoxystyrene)-5-(2,5-dimethoxyphenyl)-pyrazoline, 1-(4-methoxyphenyl)-3-(2,3-dimethoxystyryl)-5-(2,3-dimethoxyphenyl)-pyrazoline, 1-(4-methoxyphenyl)-3-(2,4-dimethoxystyryl)-5-(2,4-dimethoxyphenyl)-pyrazoline, 1-(4-tert-butyl-phenyl)-3-(3,5-dimethoxystyryl)-5-(3,5-dimethoxyphenyl)-pyrazoline, 1-(4-tert-butyl-phenyl)-3-(3,4-dimethoxystyryl)-5-(3,4-dimethoxyphenyl)-pyrazoline, 1-(4-tert-butyl-phenyl)-3-(2,6-dimethoxystyryl)-5-(2,6-dimethoxyphenyl)-pyrazoline, 1-(4-tert-butyl-phenyl)-3-(2,5-dimethoxystyryl)-5-(2,5-dimethoxyphenyl)-pyrazoline, 1-(4-tert-butyl-phenyl)-3-(2,3-dimethoxystyryl)-5-(2,3-dimethoxyphenyl)-pyrazoline, 1-(4-tert-butyl-phenyl)-3-(2,4-dimethoxystyryl)-5-(2,4-dimethoxyphenyl)-pyrazoline, 1-(4-isopropyl-phenyl)-3-(3,5-dimethoxystyryl)-5-(3,5-dimethoxyphenyl)-pyrazoline, 1-(4-isopropyl-phenyl)-3-(3,4-dimethoxystyryl)-5-(3,4-dimethoxyphenyl)-pyrazoline, 1-(4-isopropyl-phenyl)-3-(2,6-dimethoxystyryl)-5-(2,6-dimethoxyphenyl)-pyrazoline, 1-(4-isopropyl-phenyl)-3-(2,5-dimethoxystyryl)-5-(2,5-dimethoxyphenyl)-pyrazoline, 1-(4-isopropyl-phenyl)-3-(2,3-dimethoxystyryl)-5-(2,3-dimethoxyphenyl)-pyrazoline, and 1-(4-isopropyl-phenyl)-3-(2,4-dimethoxystyryl)-5-(2,4-dimethoxyphenyl)-pyrazoline.

Examples of the anthracene compound include 1-methylanthracene, 2-methylanthracene, 9-methylanthracene, 2-ethylanthracene, 2-butylanthracene, 9-vinylanthracene, 9-phenylanthracene, 1-aminoanthracene, 2-aminoanthracene, 9-(methylaminomethyl) anthracene, 9-acetylanthracene, 9-anthraldehyde, 9,10-dimethylanthracene, 9,10-dimethoxyanthracene, 9,10-diethoxyanthracene, 9,10-dipropoxyanthracene, 9,10-dibutoxyanthracene, 9,10-dipentoxyanthracene, 9,10-di(2-ethylhexyloxy) anthracene, 9,10-diphenylanthracene, 2-bromo-9,10-diphenylanthracene, 9-(4-bromophenyl)-10-phenylanthracene, 10-methyl-9-anthraldehyde, and 1,4,9,10-tetrahydroxyanthracene.

The content of the component (D) may be equal to or greater than 0.01 parts by mass, equal to or greater than 0.015 parts by mass, equal to or greater than 0.02 parts by mass, or equal to or greater than 0.025 parts by mass and may be equal to or less than 5 parts by mass, equal to or less than 1 parts by mass, equal to or less than 0.5 parts by mass, equal to or less than 0.1 parts by mass, or equal to or less than 0.05 parts by mass with respect to 100 parts by mass of the total amount of the component (A) and the component (B) from the viewpoint of photosensitivity and resolution.

### Component (E): Polymerization Inhibitor

From the viewpoint of suppressing polymerization at unexposed portions at the time of the formation of the resist pattern and improving resolution, the photosensitive resin composition may further contain a component (E): polymerization inhibitor. Examples of the polymerization inhibitor include 4-tert-butylcatechol and 2,2,6,6-tetramethyl-4-hydroxypiperidin-1-oxyl.

The content of the component (E) may be 0.001 parts by mass to 0.10 parts by mass, 0,005 parts by mass to 0.08 parts by mass, or 0.01 parts by mass to 0.06 parts by mass with respect to 100 parts by mass of the total amount of the component (A) and the component (B).

The photosensitive resin composition may further contain one or more kinds of components other than the components described above. Examples of other components include a hydrogen donor (such as bis[4-(dimethylamino)phenyl]methane, bis[4-(diethylamino)phenyl]methane, leuco crystal violet, N-phenylglycine, or the like), a dye (such as malachite green), a photochromic agent (tribromophenyl sulfone and Leuco crystal violet), a heat color stabilizer, a plasticizer (such as p-toluenesulfonamide), a pigment, a filler, a defoaming agent, a flame retardant, a stabilizer, an adhesion-imparting agent, a leveling agent, a stripping accelerator, an antioxidant, a fragrance, an imaging agent, and a thermal crosslinker. The content of other components may be equal to or greater than 0.005 parts by mass or equal to or greater than 0.01 parts by mass and may be equal to or less than 20 parts by mass with respect to 100 parts by mass of the total amount of the component (A) and the component (B).

The photosensitive resin composition may further contain one or more kinds of organic solvents from the viewpoint of adjusting viscosity. Examples of the organic solvent include methanol, ethanol, acetone, methyl ethyl ketone, methyl cellosolve, ethyl cellosolve, toluene, N,N-dimethylformamide and propylene glycol monomethyl ether. The content of the organic solvent may be equal to or greater than 40% by mass and may be equal to or less than 70% by mass with respect to the total amount of the photosensitive resin composition.

The photosensitive resin composition can be suitably used in the formation of a resist pattern and can be particularly suitably used in a method of manufacturing a wiring substrate, which will be described later.

### [Photosensitive Element]

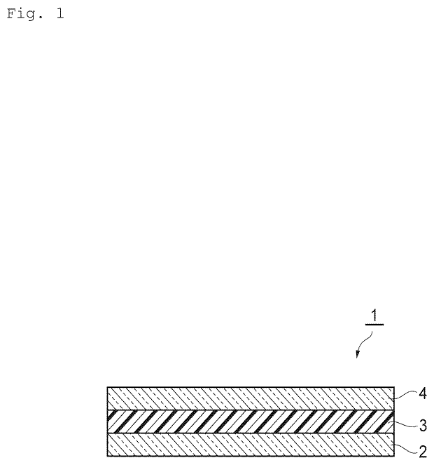

A photosensitive element according to the present embodiment includes a support and a photosensitive layer formed on the support using the photosensitive resin composition. The solid content of contained components other than volatile substances in the photosensitive layer may be within a numerical range of the solid content of each component in the photosensitive resin composition described above. In a case of using the photosensitive element according to the present embodiment, the photosensitive layer may be laminated on the substrate, and exposure may be performed without peeling off the support. FIG. 1 is a schematic sectional view of a photosensitive element according to an embodiment. As illustrated in FIG. 1, a photosensitive element 1 includes a support 2 and a photosensitive layer 3 derived from the above-described photosensitive resin composition formed on the support 2 and is configured to include a protective layer 4 and the like and other layers provided as needed.

Each of the support 2 and the protective layer 4 may be a polymer film having heat resistance and solvent resistance, and examples thereof may include polyester films such as a polyethylene terephthalate film and polyolefin films such as a polyethylene film and a polypropylene film. Each of the support 2 and the protective layer 4 may be a film of a hydrocarbon-based polymer other than polyolefin, A film of a hydrocarbon-based polymer containing polyolefin may have a low density, for example, a density of equal to or less than 1.014 g/cm³. Each of the support 2 and the protective layer 4 may be a stretched film obtained by stretching the low-density hydrocarbon-based polymer film. The kind of polymer film constituting the protective layer 4 may be the same as or different from the kind of polymer film constituting the support 2.

Each of these polymer films can be purchased as a polyethylene terephthalate film of PS series (for example, PS-25) manufactured by Teijin Limited, a polyethylene film of NE-15 or the like manufactured by Tamapoly Co., Ltd., or a polypropylene film (for example, Alphan MA-410 or E-200C) manufactured by Oji Paper Co., Ltd. or manufactured by Shin-Etsu Film Co., Ltd., for example.

The thickness of the support 2 may be equal to or greater than 1 μm or equal to or greater than 5 μm from the viewpoint that breakage of the support 2 can be reduced when the support 2 is peeled off from the photosensitive layer 3 and may be equal to or less than 100 μm, equal to or less than 50 μm, or equal to or less than 30 μm from the viewpoint that it is possible to suitably perform exposure even in a case where the exposure is performed via the support 2.

The thickness of the protective layer 4 may be equal to or greater than 1 μm, equal to or greater than 5 μm, or equal to or greater than 15 μm from the viewpoint that breakage of the protective layer 4 can be reduced when the photosensitive layer 3 and the support 2 are laminated on the substrate while the protective layer 4 is peeled off and may be equal to or less than 100 μm, equal to or less than 50 μm, or equal to or less than 30 μm from the viewpoint that productivity is improved.

The photosensitive layer 3 is formed from the above-described photosensitive resin composition. The thickness of the photosensitive layer 3 after drying (after an organic solvent is volatilized in a case where the photosensitive resin composition contains the organic solvent) may be equal to or greater than 1 μm or equal to or greater than 5 μm from the viewpoint of facilitating application and improving productivity and may be equal to or less than 100 μm, equal to or less than 50 μm, or equal to or less than 40 μm from the viewpoint of adhesion and resolution.

The photosensitive element 1 can be obtained as follows, for example. First, the photosensitive layer 3 is formed on the support 2. The photosensitive layer 3 can be formed by, for example, applying the photosensitive resin composition containing the organic solvent to form a coating layer and drying the coating layer. Then, a protective layer 4 is formed on the surface of the photosensitive layer 3 on the side opposite to the support 2.

The coating layer is formed by a known method such as roll coating, comma coating, gravure coating, air knife coating, die coating, or bar coating, for example. The drying of the coating layer is performed such that the amount of organic solvent remaining in the photosensitive layer 3 becomes equal to or less than 2% by mass, for example, and specifically, the drying is performed at 70° C. to 150° C. for 5 minutes to 30 minutes, for example.

The photosensitive element may not include a protective layer and may include other layers such as a cushion layer, an adhesive layer, a light absorbing layer, and a gas barrier layer in another embodiment.

The photosensitive element 1 may be in the sheet form or in a form of a photosensitive element roll wound around a winding core in a roll shape, for example. In the photosensitive element roll, the photosensitive element 1 is preferably wound such that the support 2 is located outside. The winding core is formed of, for example, polyethylene, polypropylene, polystyrene, polyvinyl chloride, or an acrylonitrile-butadiene-styrene copolymer. An end surface of the photosensitive element roll may be provided with an end surface separator from the viewpoint of protecting the end surface or may be provided with a moisture-proofing end surface separator from the viewpoint of edge fusion resistance. The photosensitive element 1 may be wrapped by, for example, a black sheet having low moisture permeability.

The photosensitive element 1 can be suitably used for forming a resist pattern and can be particularly suitably used in a method of manufacturing a printed wiring board, which will be described later.

### [Method of Forming Resist Pattern]

A method of forming a resist pattern according to the present embodiment may be configured to include: a process of forming a photosensitive layer on a substrate using the above-described photosensitive resin composition or the above-described photosensitive element (photosensitive layer formation process); a process of irradiating at least a part (predetermined part) of the photosensitive layer with active rays to form a photocured portion (exposure process); and a process of removing at least a part of the above-described unphotocured portion of the photosensitive layer from the substrate to form a resist pattern (developing process), and the method may further include other processes as needed. The resist pattern may be referred to as a photocured product pattern of the photosensitive resin composition or may be referred to as a relief pattern. The method of forming the resist pattern may also be referred to as a method of manufacturing a resist patterned substrate.

### (Photosensitive Layer Formation Process)

As a method of forming the photosensitive layer on the substrate, the photosensitive resin composition may be applied and dried, or the photosensitive layer of the photosensitive element may be pressure-bonded to the substrate while being heated after the protective layer is removed from the photosensitive element. In a case where the photosensitive element is used, a laminate including the substrate, the photosensitive layer, and the support stacked in this order is obtained. Although the substrate is not particularly limited, a circuit formation substrate including an insulating layer and a conductor layer formed on the insulating layer or a die pad (lead frame base material) such as an alloy base material is typically used.

In a case where the photosensitive element is used, the photosensitive layer formation process may be performed under a reduced pressure from the viewpoint of adhesion and followability. The photosensitive layer and/or the substrate may be heated at a temperature of 70° C. to 130° C. during press-bonding. Although the pressure-bonding may be performed at a pressure of about 0.1 MPa to 1.0 MPa (about 1 kgf/cm² to 10 kgf/cm²), these conditions are to be appropriately selected as needed. Note that although it is not necessary to perform preheating process of the substrate in advance if the photosensitive layer is heated to 70° C. to 130° C., it is also possible to perform the preheating process of the substrate in order to further improve adhesion and followability.

### (Exposure Process)

In the exposure process, at least a part of the photosensitive layer formed on the substrate is irradiated with active rays, and the part irradiated with the active rays is thus photocured to thereby form a latent image. At this time, although it is possible to perform the irradiation with the active rays through the support in a case where the support is present on the photosensitive layer, and the support transmits the active rays therethrough, the support is removed, and the photosensitive layer is then irradiated with the active rays in a case where the support blocks the rays.

Examples of the exposure method include a method of performing imagewise irradiation with active rays by a direct drawing exposure method such as a laser direct imaging (LDI) exposure method or a digital light processing (DLP) exposure method, a method performing imagewise irradiation with active rays via negative or positive mask pattern called an art work (mask exposure method), and a method of performing imagewise irradiation with active rays by a projection exposure method.

As a light source for the active rays, a known light source can be used, and examples of the light source to be used include light sources that effectively emit ultraviolet rays or visible light such as a carbon arc lamp, a mercury vapor arc lamp, a high-pressure mercury-vapor lamp, a xenon lamp, a gas laser such as an argon laser, a solid laser such as a YAG laser, and a semiconductor laser.

### (Developing Process)

In the developing process, at least a part of the unphotocured portion (other than the photocured portion) of the photosensitive layer is removed from the substrate to thereby form a resist pattern on the substrate.

In the case where the support is present on the photosensitive layer, the support is removed, and the region (which may also be referred to as an unexposed part) other than the photocured portion is then removed (developed). As a developing method, there are wet development and dry development, and the wet development has widely been used.

In the case of adopting wet development, the development may be performed by a known developing method using a developer corresponding to the photosensitive resin composition. Examples of the developing method include a dip method, a paddle method, a spraying method, and methods using brushing, slapping, scrubbing, swinging immersion, and the like. From the viewpoint of resolution, a high-pressure spraying method may be used as the developing method. Two or more kinds from among these methods may be combined to perform the development.

The constitution of the developer is appropriately selected in accordance with the constitution of the above-described photosensitive resin composition. Examples of the developer include an alkaline aqueous solution and an organic solvent developer.

From the standpoint of safety, stability, and satisfactory operability, an alkaline aqueous solution may be used as the developer. Examples of a base in the alkaline aqueous solution to be used include: alkali hydroxides such as lithium, sodium, and potassium hydroxides; alkali carbonates such as lithium, sodium, potassium, and ammonium carbonates or bicarbonates; alkali metal phosphates such as potassium phosphate and sodium phosphate; alkali metal pyrophosphates such as sodium pyrophosphate and potassium pyrophosphate; borax, sodium metasilicate, tetramethylammonium hydroxide, ethanolamine, ethylenediamine, diethylenetriamine, 2-amino-2-hydroxymethyl-1,3-propanediol, 1,3-diaminopropanol-2, and morpholine.

As the alkaline aqueous solution to be used for the development, a dilute solution of 0.1% by mass to 5% by mass sodium carbonate, a dilute solution of 0.1% by mass to 5% by mass potassium carbonate, a dilute solution of 0.1% by mass to 5% by mass sodium hydroxide, or a dilute solution of 0.1% by mass to 5% by mass sodium tetraborate, for example, can be used. pH of the alkaline aqueous solution may be in the range of 9 to 11, and the temperature thereof can be adjusted in accordance with the alkaline developability of the photosensitive layer. For example, a surfactant, a defoaming agent, a small amount of an organic solvent for promoting the development, and the like may be mixed into the alkaline aqueous solution.

Examples of the organic solvent to be used in the alkaline aqueous solution include acetone, ethyl acetate, alkoxyethanol having an alkoxy group having 1 to 4 carbon atoms, ethyl alcohol, isopropyl alcohol, butyl alcohol, diethylene glycol monomethyl ether, diethylene glycol monoethyl ether, and diethylene glycol monobutyl ether.

Examples of the organic solvent to be used in the organic solvent developer include 1,1,1-trichloroethane, N-methyl-2-pyrrolidone, N,N-dimethylformamide, cyclohexanone, methylisobutyl ketone, and γ-butyrolactone. To prevent flaming, water may be added within a range of 1% by mass to 20% by mass to the organic solvent to thereby obtain the organic solvent developer.

The method of forming a resist pattern in the present embodiment may include a process of further curing the resist pattern by performing heating at about 60° C. to 250° C. or exposure at about 0.2 J/cm² to 10 J/cm² as needed after the uncured part is removed in the developing process.

### [Method of Manufacturing Printed Wiring Board]

A method of manufacturing a printed wiring board according to the present embodiment includes a process of performing etching process or plating process on a substrate with a resist pattern formed thereon by the above-described method of forming a resist pattern to thereby form a conductor pattern, and the method may also be configured to include other processes such as the resist pattern removal process as needed.

In the plating process, plating process is performed on the conductor layer provided on the substrate using the resist pattern formed on the substrate as a mask. The conductor pattern may be formed by removing the resist by removing a resist pattern, which will be described later, after the plating process and further etching the conductor layer covered with the resist. A method of the plating process may be either electrolytic plating process or electroless plating process and may be electroless plating process.

On the other hand, the conductor layer provided on the substrate is etched away using the resist pattern formed on the substrate as a mask to thereby form a conductor pattern in the etching process. A method of the etching process is appropriately selected in accordance with the conductor layer to be removed. Examples of an etching solution include a copper(II) chloride solution, an iron(II) chloride solution, an alkali etching solution, and a hydrogen peroxide-based etching solution.

After the etching process or the plating process, the resist pattern on the substrate may be removed. For removal of the resist pattern, the resist pattern can be released with, for example, a stronger alkaline aqueous solution than the alkaline aqueous solution used in the above developing process, for example. Examples of the strong alkaline aqueous solution to be used include 1% by mass to 10% by mass of aqueous solution of sodium hydroxide and 1% by mass to 10% by mass of aqueous solution of potassium hydroxide.

In the case where the resist pattern is removed after the plating process is performed, it is possible to manufacture a desired printed wiring board by further performing etching process to etch the conductor layer covered with the resist to form a conductor pattern. A method of the etching process at this time is appropriately selected in accordance with the conductor layer to be removed. For example, the above-described etching solution can be applied.

The method of manufacturing the printed wiring board according to the present embodiment can be applied not only to manufacturing of a single-layer printed wiring board but also to manufacturing of a multilayer printed wiring board and can also be applied to manufacturing of a printed wiring board including a small-diameter through-hole and the like.

### EXAMPLES

Although the present invention will be more specifically described below on the basis of Examples, the present invention is not limited to these Examples.

### [Synthesis of Binder Polymer]

Compounds having Tg of homopolymers shown below were prepared as polymerizable monomers.
AA: Acrylic acid (Tg: 106° C.)
MAA: Methacrylic acid (Tg: 228° C.)
ST: Styrene (Tg: 100° C.)
TCDMA: Dicyclopentanyl methacrylate (Tg: 175° C.)
HEMA: Hydroxyethyl methacrylate (Tg: 55° C.)
BZMA: Benzyl methacrylate (Tg: 54° C.)

### Synthesis Example 1

87.8 g of acrylic acid (AA), 104.8 g of methacrylic acid (MAA), 137.8 g of dicyclopentanyl methacrylate (TCDMA), and 104.3 g of benzyl methacrylate (BZMA) (mass ratio AA/MAA/TCDMA/BZMA=20.2/24.1/31.7/24.0) as polymerizable monomers, 2.2 g of azobisisobutyronitrile (AIBN) as a thermal radical polymerization initiator, and 129.5 g of propylene glycol monomethyl ether as a solvent were mixed to prepare a mixture (x). A solution (a) was prepared by dissolving 5.5 g of AIBN in 26.3 g of propylene glycol monomethyl ether.

To a flask equipped with a stirring device, a dripping funnel, a condenser, a thermometer, and a gas inlet tube, 45.6 g of propylene glycol monomethyl ether and 175.1 g of toluene were added, the mixture was stirred in a nitrogen atmosphere with replacement of gas, and the temperature was raised to 80° C. Then, the mixture (x) was added dropwise into the flask over 2 hours. After the completion of the dropwise addition, the mixture was stirred at 80° C. for 2 hours, the solution (a) was added thereto, and stirring was further performed for 3 hours. Then, the temperature of the solution in the flask was raised to 100° C. over 20 minutes while the stirring was continued, and stirring was performed at 100° C. for 2 hours. Then, 93.7 g of propylene glycol monomethyl ether and 74.3 g of toluene were added thereto, and the mixture was cooled to a room temperature while being stirred, to thereby obtain a solution (solid content: 50% by mass) of a binder polymer (A-1).

### Synthesis Example 2

A solution of a binder polymer (A-2) (solid content: 50% by mass) was obtained under conditions similar to those in Synthesis Example 1 other than that the kinds and the amounts of polymerizable monomers in the mixture (x) were changed to polymerizable monomers and the mass ratios shown in Table 1.

### Synthesis Example 3

A solution of a binder polymer (A-3) (solid content: 50% by mass) was obtained under conditions similar to those in Synthesis Example 1 other than that the kinds and the amounts of polymerizable monomers in the mixture (x) were changed to polymerizable monomers and the mass ratios shown in Table 1.

### Synthesis Examples 4 to 9

Solutions (solid content: 50% by mass) of binder polymers (A-4) to (A-9) were obtained under conditions similar to those in Synthesis Example 1 other than that the kinds and the amounts of polymerizable monomers in the mixture (x) were changed to the polymerizable monomers and the mass ratios shown in Tables 1 and 2.

TABLE 1

| Binder polymer | | A-1 | A-2 | A-3 | A-4 | A-5 |
|---|---|---|---|---|---|---|
| Polymer- | AA | 20.2 | 21.4 | — | 44.3 | — |
| izable | MAA | 24.1 | 23.5 | 27 | — | 44.3 |
| monomer | ST | — | — | 50 | — | — |
| | TCDMA | 31.7 | 55.1 | — | 31.7 | 31.7 |
| | HEMA | — | — | 3 | — | — |
| | BZMA | 24.0 | — | 20 | 24.0 | 24.0 |

| | | | | | |
|---|---|---|---|---|---|
| Mw | 50000 | 46600 | 45000 | 43000 | 42000 |
| Tg(° C.) | 106 | 125 | 114 | 128 | 157 |
| Acid value (mgKOH/g) | 149 | 157 | 174 | 342 | 240 |

TABLE 2

| Binder polymer | | A-6 | A-7 | A-8 | A-9 |
|---|---|---|---|---|---|
| Polymerizable | AA | 14.3 | 20.2 | 20.2 | 20.2 |
| monomer | MAA | 29.7 | 24.1 | 24.1 | 24.1 |
| | TCDMA | 32.0 | 20.0 | 35.0 | 15.7 |
| | BZMA | 24.0 | 35.7 | 20.7 | 40.0 |

| | | | | |
|---|---|---|---|---|
| Mw | 43000 | 44000 | 43000 | 42000 |
| Tg(° C.) | 140 | 120 | 138 | 113 |
| Acid value (mgKOH/g) | 116 | 145 | 153 | 153 |

### (Weight Average Molecular Weight)

As a sample for Mw measurement, a polymer solution was dissolved in tetrahydrofuran (THF) to prepare 0.2% by mass of THE solution. Mw was measured by gel permeation chromatography (GPC) method and was derived by conversion using a standard polystyrene calibration curve. The conditions for the GPC are as follows.

Measurement apparatus: Shodex (registered trademark) GPC-101 (manufactured by Resonac Corporation)
Detector: Differential refractometer (Shodex RI-71S) (manufactured by Resonac Corporation)
Column: Shodex LF-804+LF-804 (manufactured by Resonac Corporation)
Column temperature: 40° C.
Eluent: THE
Flow rate: 1 mL/min

### (Glass Transition Temperature)

Tg of the binder polymer was calculated by the Fox equation.

### (Acid Value)

In accordance with JIS K6901: 2008 5.3.2, the acid value of the binder polymer was measured by a neutralization titration method.

### [Photosensitive Resin Composition]

Photosensitive resin compositions were prepared by mixing 57.0 parts by mass of solid content of the binder polymer solution with components in blending amounts (parts by mass) shown in Tables 3 and 4. Details of the components shown in Tables 3 and 4 are as follows.

### (Photopolymerizable Compounds)

FA-321M: 2,2-bis(4-(methacryloxypentaethoxy)phenyl)propane (manufactured by Resonac Corporation)
FA-024M: EOPO-modified dimethacrylate (manufactured by Resonac Corporation)
BP-2EM: 2,2-bis(4-(methacryloxydiethoxy)phenyl)propane (manufactured by Kyoeisha Chemical Co., Ltd.)

### (Photopolymerization Initiator)

B-CIM: 2,2′-bis(2-chlorophenyl)-4,4′,5,5′-tetraphenylbiimidazole (manufactured by Hampford)

### (Sensitizer)

PZ-501D: 1-phenyl-3-(4-methoxystyryl)-5-(4-methoxyphenyl) pyrazoline (manufactured by Nippon Chemical Works Co., Ltd.)

### (Polymerization Inhibitor)

Q-TBC-5P: 4-tert-butylcatechol (manufactured by DIC Corporation)
LA-7RD: 2,2,6,6-tetramethyl-4-hydroxypiperidin-1-oxyl (from ADEKA Corporation)

### (Photochromic Agent)

LCV: Leuco crystal violet (manufactured by Yamada Chemical Co., Ltd.)

### (Adhesion-Imparting Agent)

SF-808H: mixture of carboxybenzotriazole, 5-amino-1H-tetrazole, and methoxypropanol (manufactured by Sanwa Kasei Corporation)

### (Dye)

MKG: malachite green (manufactured by Osaka Organic Chemical Industry Ltd.)

### [Photosensitive Element]

As a support, a polyethylene terephthalate film (manufactured by Toray Industries, Inc., trade name: “QS-69”) with a thickness of 16 μm was prepared. After the photosensitive resin composition was applied to the support, the photosensitive resin composition was successively dried in hot air convection driers at 80° C. and 120° C. to form a photosensitive layer with a thickness of 25 μm after the drying. A polyethylene film (manufactured by Tamapoly Co., Ltd., trade name: “NF-15”) was adhered as a protective layer onto the photosensitive layer, and a photosensitive element in which the support, the photosensitive layer, and the protective layer were laminated in this order was obtained.

### [Laminate]

A copper-clad laminate (manufactured by Resonac Corporation, trade name: “MCL-E-679”) which was a glass epoxy material with copper foils (thickness: 35 μm) disposed on both sides thereof was surface-treated by washing with water, washing with acid and washing with water and was then dried with an air flow. The surface-treated copper-clad laminate was warmed to 80° C., and the photosensitive element was laminated on the copper-clad laminate such that the photosensitive layer was in contact with the copper surface while the protective layer was peeled off. In this manner, a laminate in which the copper-clad laminate, the photosensitive layer, and the support were laminated in this order was obtained. The lamination was carried out using a heat roll at 110° C. with a pressure-bonding pressure of 0.4 MPa at a roll rate of 1.05 m/min.

### [Evaluation]

### (Followability)

The photosensitive layer and the support were laminated on a slide glass while the protective layer was peeled off from the photosensitive element to produce a test piece for followability measurement. The lamination was carried out using a roll at 25° C. with a pressure of 0.4 MPa at a roll rate of 1.0 m/min such that the photosensitive layer of the photosensitive element was in contact with the surface of the slide glass. For the produced test piece, the maximum push-in depth from the side of the support was measured using a hardness meter (manufactured by Fischer Instruments Co., Ltd., FISCHERSCOPE H100SMC). As an indenter, an indenter with a φ0.4 mm spherical surface was used to measure the maximum push-in depth when a load was held for 5 seconds after loading at 300 mN/10 seconds, and the maximum push-in depth was regarded as a push-in value. The larger push-in value means better followability.

### (Releasability)

A chrome-on-glass photomask (having a planar pattern of 50 mm×40 mm) was used as a releasing test evaluation negative on the support of the laminate, and the photosensitive layer was exposed using a projection exposure machine (UX-2240SM) in the exposure amount such that the number of remaining steps of the Hitachi 41-step tablet was 14. After the exposure, the support was peeled off to expose the photosensitive layer, 18 by mass of aqueous solution of sodium carbonate at 30° C. was sprayed for a time that was double the minimum developing time, and the unexposed parts were removed.

After the development process, immersion into an amine release solution (15% by volume of R-100S+8% by volume of R-101 aqueous solution, manufactured by Mitsubishi Gas Chemical Company, Inc.) heated to 50° C. was performed. The time until the photosensitive layer was completely removed was measured and was regarded as the releasing time. The shorter releasing time means better releasability. In Comparative Example 2, it was not possible to perform lamination when the laminate was produced, and it was thus not possible to evaluate releasability.

TABLE 3

| | | | Compara- | Compara- | |
|---|---|---|---|---|---|
| | Example | Example | tive | tive | Comparative |
| | 1 | 2 | Example 1 | Example 2 | Example 3 |
| A-1 | 57.0 | — | — | — | — |
| A-2 | — | 57.0 | — | — | — |
| A-3 | — | — | 57.0 | — | — |
| A-4 | — | — | — | 57.0 | — |
| A-5 | — | — | — | — | 57.0 |
| FA-321M | 34.5 | 34.5 | 34.5 | 34.5 | 34.5 |
| FA-024M | 2.5 | 2.5 | 2.5 | 2.5 | 2.5 |
| BP-2EM | 6.0 | 6.0 | 6.0 | 6.0 | 6.0 |
| B-CIM | 5.5 | 5.5 | 5.5 | 5.5 | 5.5 |
| PZ-501D | 0.027 | 0.027 | 0.027 | 0.027 | 0.027 |
| Q-TBC-5P | 0.04 | 0.04 | 0.04 | 0.04 | 0.04 |
| LA-7RD | 0.01 | 0.01 | 0.01 | 0.01 | 0.01 |
| LCV | 0.77 | 0.77 | 0.77 | 0.77 | 0.77 |
| SF-808H | 1.0 | 1.0 | 1.0 | 1.0 | 1.0 |
| MKG | 0.05 | 0.05 | 0.05 | 0.05 | 0.05 |
| Acetone | 10 | 10 | 10 | 10 | 10 |
| Toluene | 10 | 10 | 10 | 10 | 10 |
| Methanol | 6 | 6 | 6 | 6 | 6 |
| Followa- | 12.5 | 9.3 | 7.2 | 15.6 | 5.5 |
| bility (μm) | | | | | |
| Releasa- | 20 | 19 | 35 | — | 38 |
| bility | | | | | |
| (second) | | | | | |

TABLE 4

| | Example 3 | Example 4 | Example 5 | Example 6 |
|---|---|---|---|---|
| A-6 | 57.0 | — | — | — |
| A-7 | — | 57.0 | — | — |
| A-8 | — | — | 57.0 | — |
| A-9 | — | — | — | 57.0 |
| FA-321M | 34.5 | 34.5 | 34.5 | 34.5 |
| FA-024M | 2.5 | 2.5 | 2.5 | 2.5 |
| BP-2EM | 6.0 | 6.0 | 6.0 | 6.0 |
| B-CIM | 5.5 | 5.5 | 5.5 | 5.5 |
| PZ-501D | 0.027 | 0.027 | 0.027 | 0.027 |
| Q-TBC-5P | 0.04 | 0.04 | 0.04 | 0.04 |
| LA-7RD | 0.01 | 0.01 | 0.01 | 0.01 |
| LCV | 0.77 | 0.77 | 0.77 | 0.77 |
| SF-808H | 1.0 | 1.0 | 1.0 | 1.0 |
| MKG | 0.05 | 0.05 | 0.05 | 0.05 |
| Acetone | 10 | 10 | 10 | 10 |
| Toluene | 10 | 10 | 10 | 10 |
| Methanol | 6 | 6 | 6 | 6 |
| Followability(μm) | 7.8 | 13.4 | 10.5 | 12 |
| Releasability (second) | 33 | 30 | 22 | 34 |

### REFERENCE SIGNS LIST

1 Photosensitive element
2 Support
3 Photosensitive layer
4 Protective layer

1. A photosensitive resin composition comprising: a binder polymer; a photopolymerizable compound; and a photopolymerization initiator,
wherein the binder polymer has a structural unit derived from acrylic acid and a structural unit derived from methacrylic acid.

2. The photosensitive resin composition according to claim 1, wherein the binder polymer further has a structural unit derived from a (meth)acrylate compound having an alicyclic structure.

3. The photosensitive resin composition according to claim 1, wherein the binder polymer further has a structural unit derived from a (meth)acrylic acid aryl ester.

4. The photosensitive resin composition according to claim 1, wherein a total content of the structural unit derived from acrylic acid and the structural unit derived from methacrylic acid is 25% by mass to 45% by mass with respect to a total mass of structural units derived from polymerizable monomers constituting the binder polymer.

5. The photosensitive resin composition according to claim 1, wherein a content of a structural unit derived from styrene or a styrene derivative in the binder polymer is 0% by mass to 19% by mass with respect to a total mass of structural units derived from polymerizable monomers constituting the binder polymer.

6. A photosensitive element comprising: a support; and a photosensitive layer formed on the support using the photosensitive resin composition according to claim 1.

7. A method of forming a resist pattern, comprising:
forming a photosensitive layer on a substrate using the photosensitive resin composition according to claim 1;
irradiating at least a part of the photosensitive layer with active rays to form a photocured portion; and
removing an unphotocured portion of the photosensitive layer from the substrate to form a resist pattern.

8. A method of forming a resist pattern, comprising:
forming a photosensitive layer on a substrate using the photosensitive element according to claim 6;
irradiating at least a part of the photosensitive layer with active rays to form a photocured portion; and
removing an unphotocured portion of the photosensitive layer from the substrate to form a resist pattern.

9. A method of manufacturing a printed wiring board, comprising:
performing etching process or plating process on a substrate with a resist pattern formed thereon by the method of forming a resist pattern according to claim 7 to form a conductor pattern.

10. A method of manufacturing a printed wiring board, comprising:
performing etching process or plating process on a substrate with a resist pattern formed thereon by the method of forming a resist pattern according to claim 8 to form a conductor pattern.
